(19) United States
(12) Patent Application Publication
(10) Pub. No.: US 2023/0420405 A1
(43) Pub. Date: Dec. 28, 2023

(54) RIBBON BONDING GROUND PLANE FOR RADIO FREQUENCY PERFORMANCE IMPROVEMENT IN ELECTRO-OPTICAL DEVICES

(71) Applicant: Lumentum Operations LLC, San Jose, CA (US)

(72) Inventors: Flavio DELL'ORTO, Desio (IT); Roberto GALEOTTI, Giussago (IT); Luca MAURI, Milano (IT)

(21) Appl. No.: 17/957,899

(22) Filed: Sep. 30, 2022

Related U.S. Application Data
(60) Provisional application No. 63/355,366, filed on Jun. 24, 2022.

(51) Int. Cl. H01L 23/00; H01L 25/16

(52) U.S. Cl. CPC H01L 24/49; H01L 25/167; H01L 24/48; H01L 2224/48091; H01L 2224/48137; H01L 2224/49052; H01L 2224/4917; H01L 2224/49175; H01L 2224/49177; H01L 2224/49112; H01L 2224/49113

(57) ABSTRACT

In some implementations, an electro-optical device includes a first substrate including a first ground pad and a first signal pad; a second substrate including a second ground pad and a second signal pad, wherein the first signal pad and the second signal pad form a signal pad pair, wherein the first substrate is separated from the second substrate by less than a threshold amount; wherein the first substrate is configured to receive an optical component and the second substrate is configured to receive an electrical component that is couplable to the optical component via a wire bonding between the first signal pad and the second signal pad; and a planar ribbon bonding connecting the first ground pad to the second ground pad and diagonally crossing the wire bonding.

### CROSS-REFERENCE TO RELATED APPLICATION

This patent application claims priority to U.S. Provisional Patent Application No. 63/355,366, filed on Jun. 24, 2022, and entitled “WIRE BONDING INTERCONNECTION BETWEEN COPLANAR STRUCTURES.” The disclosure of the prior application is considered part of and is incorporated by reference into this patent application.

### TECHNICAL FIELD

The present disclosure relates generally to electro-optical devices and to a ribbon bonding ground plane for radio frequency performance improvement in electro-optical devices.

### BACKGROUND

Electro-optical devices may include components disposed on multiple different substrates. For example, integrated circuits, optical emitters, controllers, and/or other components may be disposed on different substrates within an electro-optical device. Electrical connection between different components on different substrates may be achieved using bond wires. For example, a bond wire may connect an output of a controller to an input of an optical emitter to enable the controller to control the optical emitter. This may enable connection between the different components without manufacturing a new substrate to support the different components, thereby providing flexibility in design of electro-optical devices. Bond wires may introduce inductance at high radio frequencies. The inductance may be based on a bond wire diameter, a bond wire material, a bond wire length, a frequency of operation, a height that the bond wire reaches above one or more substrates, or a separation between pairs of bond wires, among other examples.

### SUMMARY

In some implementations, an electro-optical device includes a first substrate including a first set of ground pads and a first signal pad disposed between a first ground pad and a second ground pad of the first set of ground pads; a second substrate including a second set of ground pads and a second signal pad disposed between a third ground pad and a fourth ground pad of the second set of ground pads, wherein the first ground pad is aligned to the third ground pad to form a first ground pad pair, the second ground pad is aligned to the fourth ground pad to form a second ground pad pair, and the first signal pad is aligned to the second signal pad to form a signal pad pair; a set of wire bondings including a first wire bonding connecting the first ground pad pair, a second wire bonding connecting the second ground pad pair, and a third wire bonding connecting the first signal pad and the second signal pad; an optical emitter associated with the first substrate and electrically connected to an electrical signal component associated with the second substrate via the third wire bonding; and a planar ribbon bonding connecting the first ground pad to the fourth ground pad, wherein the planar ribbon bonding crosses the third wire bonding without contacting the third wire bonding.

In some implementations, an electro-optical device includes an optical emitter disposed on a first substrate; and a signal controller for the optical emitter disposed on a second substrate, wherein the first substrate and the second substrate include at least one ground pad pair connected by a corresponding at least one ground pad wire bonding, wherein the first substrate and the second substrate include at least one signal pad pair connected by a corresponding at least one signal pad wire bonding and electrically connecting the optical emitter to the signal controller, and wherein the first substrate and the second substrate are connected by at least one planar ribbon bonding from at least one first ground of the first substrate to at least one second ground of the second substrate such that the at least one planar ribbon bonding crosses the at least one signal pad wire bonding.

In some implementations, an electro-optical device includes a first substrate including a first ground pad and a first signal pad; a second substrate including a second ground pad and a second signal pad, wherein the first signal pad and the second signal pad form a signal pad pair, wherein the first substrate is separated from the second substrate by less than a threshold amount; wherein the first substrate is configured to receive an optical component and the second substrate is configured to receive an electrical component that is couplable to the optical component via a wire bonding between the first signal pad and the second signal pad; and a planar ribbon bonding connecting the first ground pad to the second ground pad and diagonally crossing the wire bonding.

### BRIEF DESCRIPTION OF THE DRAWINGS

FIGS. 1A-1B are diagrams of an example electro-optical device associated with a ribbon bonding ground plane.

FIGS. 2A-2E are diagrams of an example layouts-240 of an electro-optical device associated with a ribbon bonding ground plane.

FIG. 3 is a diagram of an example electro-optical device associated with a ribbon bonding ground plane.

FIGS. 4A-4C are diagrams of an example responses of example electro-optical devices with and without a ribbon bonding ground

### DETAILED DESCRIPTION

The following detailed description of example implementations refers to the accompanying drawings. The same reference numbers in different drawings may identify the same or similar elements.

Bond wires connecting electro-optical components disposed on different substrates can induce inductance when used for high radio frequency (RF) operations. This inductance, which may be referred to as “parasitic inductance” can be reduced by minimizing a separation between the substrates, thereby reducing a length of the bond wires, which may also be referred to as “wire bondings.” For example, a first substrate, onto which a first component is attached, may be coplanar with a second substrate, onto which a second component is attached, and a wire bonding may cross a gap between the first and second substrate. In some examples, the wire bonding may extend both vertically and laterally. In other words, rather than a wire bonding being coplanar with the substrates, the wire bonding may extend up above a surface of the substrates (and components thereon) forming an arched or rectangular profile or cross-section.

Reduction of the parasitic inductance can be achieved by disposing a ground plane below the wire bonding. For example, a grounded metal layer may be disposed coplanar with and between a first substrate and a second substrate and a wire bonding may extend upward from the first substrate and the second substrate above the ground plane. However, to attach the ground plane layer to, for example, grounded pads of the first substrate and the second substrate, the first substrate and the second substrate may have additional separation, which may extend a length of the wire bonding. Additionally, or alternatively, a shim may be attached between the substrates with a conductive epoxy or a welding connection to enable manufacture of the ground plane layer. However, adding a shim and a conductive connection may add manufacturing complexity and make high volume manufacturing difficult.

Rather than a monolithic grounding layer, a grounding ribbon can be disposed under the wire bond to reduce parasitic inductance. For example, the grounding ribbon and the wire bonding are colinear between the first substrate and the second substrate. Because the grounding ribbon is wider than the wire bonding, the grounding ribbon forms a grounding plane beneath the wire bonding. However, positioning a grounding ribbon colinear with a wire bonding results in additional separation between the substrates which increases parasitic inductance. This may reduce a benefit (e.g., an amount of parasitic inductance reduction) that is achieved by disposing the grounding ribbon under the wire bond.

Some implementations described herein provide a ribbon bonding ground plane that is not colinear with a wire bonding. For example, the ribbon bonding may extend from a first ground pad on a first substrate and on a first side of a wire bonding to a second ground pad on a second substrate and on a second side of the wire bonding. In this case, the ribbon bonding crosses the wire bonding rather than being colinear with the wire bonding. Based on the ribbon bonding crossing the wire bonding a separation between the first substrate and the second substrate can be reduced relative to a colinear ribbon bonding, thereby reducing a length of the wire bonding. Based on reducing a length of the wire bonding and the ribbon bonding providing a ground plane for the wire bonding, implementations described herein reduce parasitic inductance relative to other techniques for connecting multiple substrates for high RF operations.

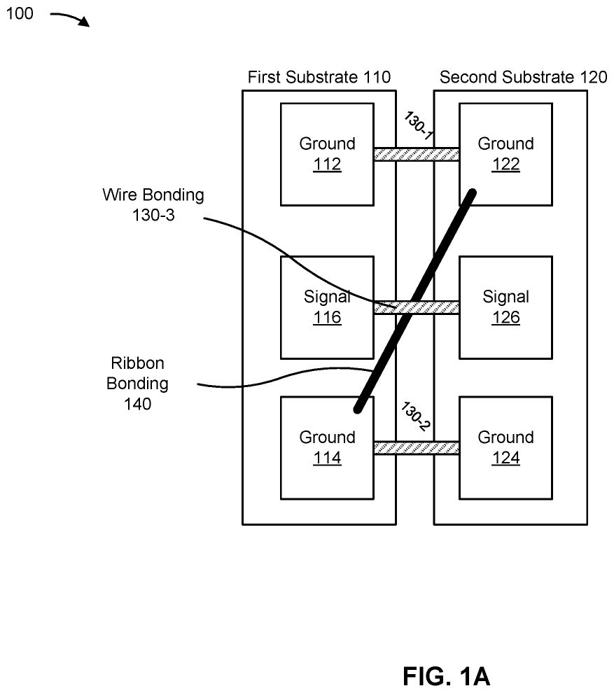

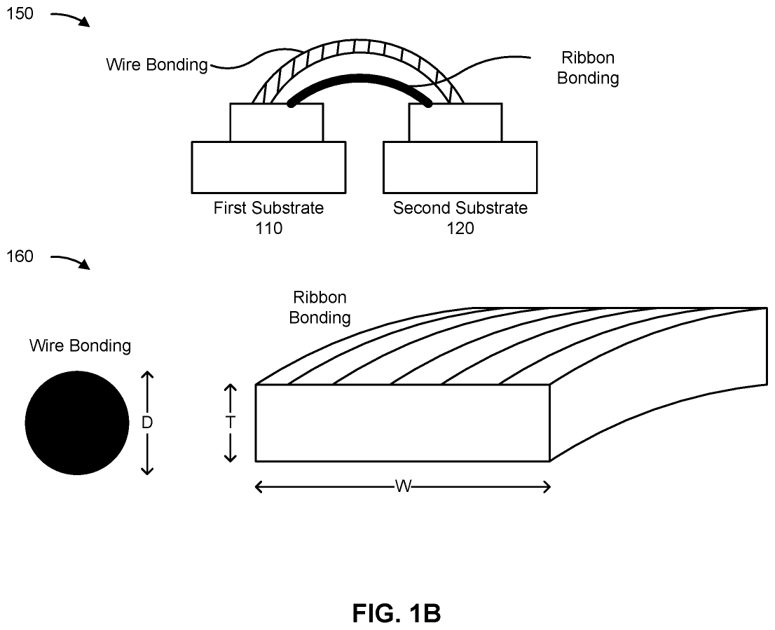

FIGS. 1A-1B are diagrams of an example electro-optical device 100 associated with a ribbon bonding ground plane. As shown in FIGS. 1A-1B, electro-optical device 100 includes a first substrate 110 and a second substrate 120. The first substrate 110 includes a first ground pad 112, a second ground pad 114, and a first signal pad 116. The second substrate 120 includes a third ground pad 122, a fourth ground pad 124, and a second signal pad 126.

In some implementations, first substrate 110 may be coplanar with second substrate 120. For example, first substrate 110 and second substrate 120 may have approximately coplanar surfaces onto which approximately coplanar bond pads are disposed (e.g., the ground pads and the signal pads). In some implementations, first substrate 110 may be separated from second substrate 120 by less than a threshold amount. For example, based at least in part on using a crossing ribbon connector rather than a colinear ribbon connector, as described in more detail herein, a separation between first substrate 110 and second substrate 120 may be less than 400 micrometers (μm), less than 200 μm, less than 100 μm, less than 50 μm, less than 25 μm, less than 10 μm, or less than 5 μm, among other examples.

As further shown in FIG. 1A, the first substrate 110 may connect to the second substrate 120 via a set of wire bondings, which may also be referred to as “wire bonds.” For example, first ground pad 112 may connect (e.g., via a first wire bonding 130-1) to third ground pad 122 to form a first ground pad pair, second ground pad 114 may connect (e.g., via a second wire bonding 130-2) to fourth ground pad 124 to form a second ground pad pair, and first signal pad 116 may connect (e.g., via a third wire bonding 130-3) to second signal pad 126 to form a signal pad pair. The signal pad pair may enable electrical connection between electro-optical components (not shown), such as an optical emitter, a controller, or a power source, among other examples, of electro-optical device 100.

As further shown in FIG. 1A, first substrate 110 may connect to second substrate 120 via a ribbon bonding 140. The ribbon bonding 140 may connect between non-paired ground pads, such that the ribbon bonding 140 crosses wire bonding 130-3 without making contact with wire bonding 130-3 (and without crossing wire bonding 130-1 or wire bonding 130-2). By arranging ribbon bonding 140 in a diagonal arrangement, as shown, ribbon bonding 140 extends a greater distance than in a colinear arrangement. In other words, a distance between third ground pad 122 and second ground pad 114 is greater than a distance between signal pad 116 and signal pad 126. Accordingly, when, to achieve manufacturability, the ribbon bonding 14 is to be associated with at least a particular length, the particular length is achieved in a diagonal arrangement with less separation between first substrate 110 and second substrate 120 than is achieved in a colinear arrangement. In this case, ribbon bonding 140 grounds an electrical inductance (e.g., a parasitic inductance) associated with high RF operation of components of electro-optical device 100 that are connected via the signal pad pair and wire bonding 130-3. In this way, based on ribbon bonding 140 connecting between non-paired ground pads, a minimum ribbon bonding length (e.g., for manufacturability) can be achieved with less separation than if ribbon bonding 140 were to be colinear with wire bonding 130-3.

As shown in FIG. 1B, and by side-view diagram 150, ribbon bonding 140 may be disposed below wire bonding 130-3. In another example, ribbon bonding 140 may be disposed above wire bonding 130-3. In another example, ribbon bonding 140 may be disposed both above and below wire bonding 130-3. In other words, a first ribbon bonding 140 may be disposed above wire bonding 130-3 and a second ribbon bonding 140 may be disposed below wire bonding 130-3. In this case, disposing ribbon bonding 140 both above and below wire bonding 130-3 achieves improves S11 and S21 performance, as described herein.

As further shown in FIG. 1B, and by diagram 160, ribbon bonding 140 may be a planar ribbon bonding. For example, ribbon bonding 140 may have a rectangular cross-section with a width (W) and a thickness (T). In contrast, wire bonding 130-3 may have a circular cross-section with a diameter (D). In some implementations, the ribbon bonding 140 may have at least a threshold aspect ratio (e.g., a ratio of the width to the thickness). For example, the ribbon bonding 140 may have an aspect ratio of at least 2 (e.g., a width to thickness ratio of at least 2:1), at least 4, at least 8, at least 16, at least 32, at least 64, at least 128, or at least 256, among other examples. In some implementations, the ribbon bonding 140 may have a width of approximately 50 μm and a thickness of approximately 6 μm. Reducing a thickness of the ribbon bonding 140 may enable the ribbon bonding 140 to remain lower above respective surfaces of the first substrate 110 and the second substrate 120, thereby reducing a likelihood of contacting wire bonding 130-3 and short circuiting wire bonding 130-3. In some implementations, a ratio of the width of ribbon bonding 140 to the diameter of wire bonding 130-3 may be at least 4, at least 8, at least 16, at least 32, at least 64, at least 128, or at least 256, among other examples. In this way, ribbon bonding 140 forms a ground plane for wire bonding 130-3, thereby reducing parasitic inductance for wire bonding 130-3.

In some implementations, ribbon bonding 140 may have a particular structure and/or a particular material. For example, ribbon bonding 140 may be a flexible ribbon connector that includes a metallic material. In some implementations, ribbon bonding 140 may include a cladding material (e.g., a dielectric material or an insulator material). Additionally, or alternatively, ribbon bonding 140 may be a rigid ribbon connector. In some implementations, ribbon bonding 140 is non-insulated. For example, ribbon bonding 140 may be formed from bare ribbon wire. In this case, ribbon bonding 140 may have an air gap (or other non-conductive medium gap, such as another gas) separating ribbon bonding 140 from wire bonding 130-3. Alternatively, ribbon bonding 140 may be insulated. For example, ribbon bonding 140 may be a ribbon connector coated with an insulative material. In this case, the insulated material may prevent ribbon bonding 140 from touching wire bonding 130-3, thereby enabling ribbon bonding 140 to be positioned closer to wire bonding 130-3 (e.g., without risk of electrically grounding wire bonding 130-3 as a result of accidental touching) and further reduce parasitic inductance (e.g., by being positioned closer together).

As indicated above, FIGS. 1A-1B are provided as an example. Other examples may differ from what is described with regard to FIGS. 1A-1B.

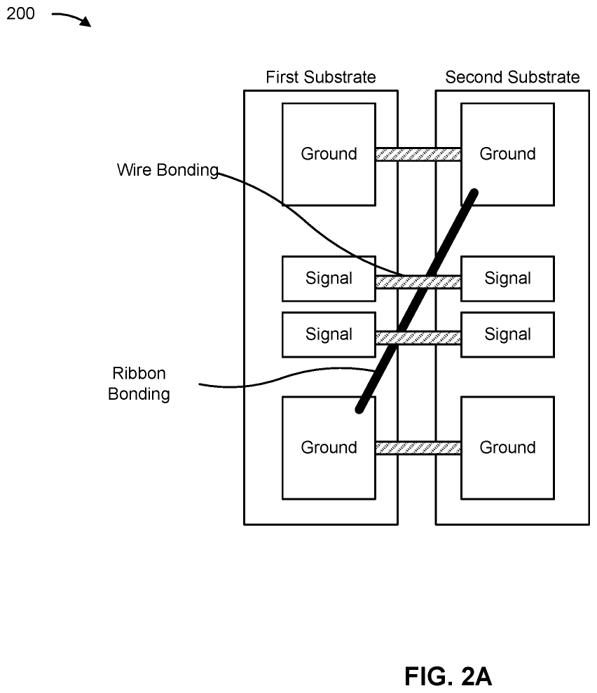

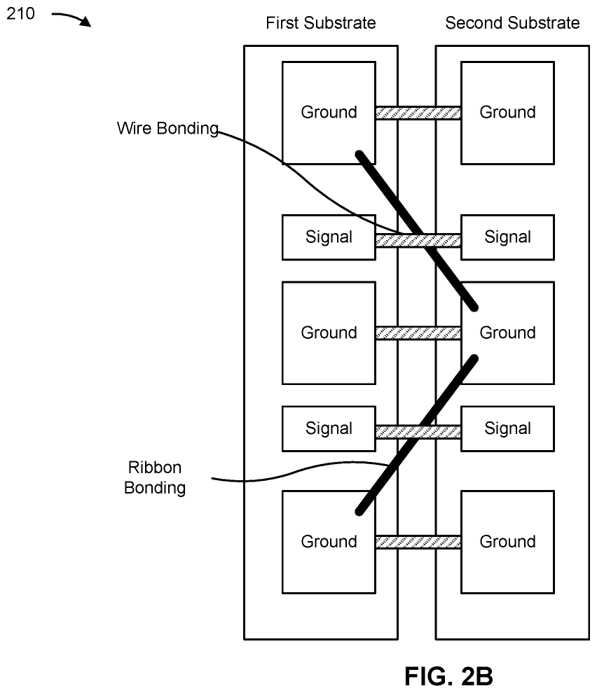

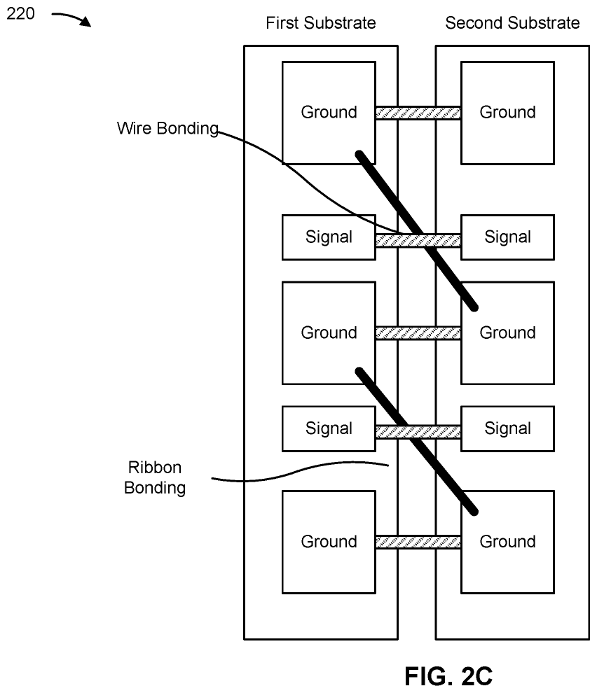

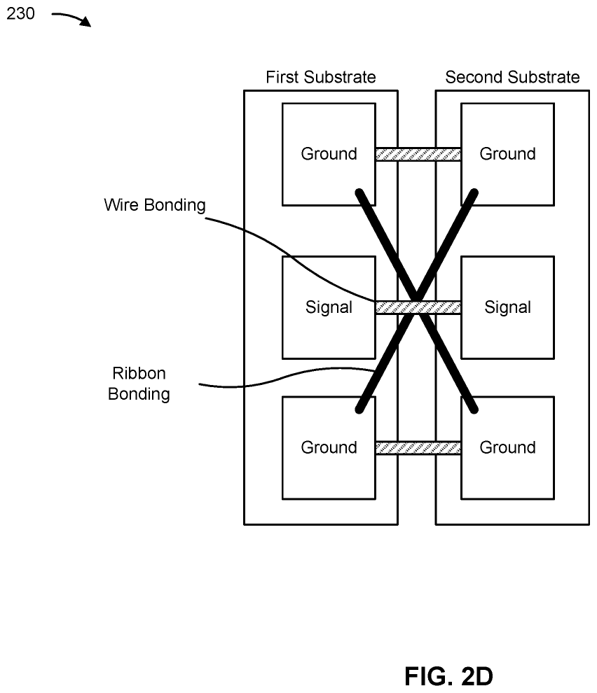

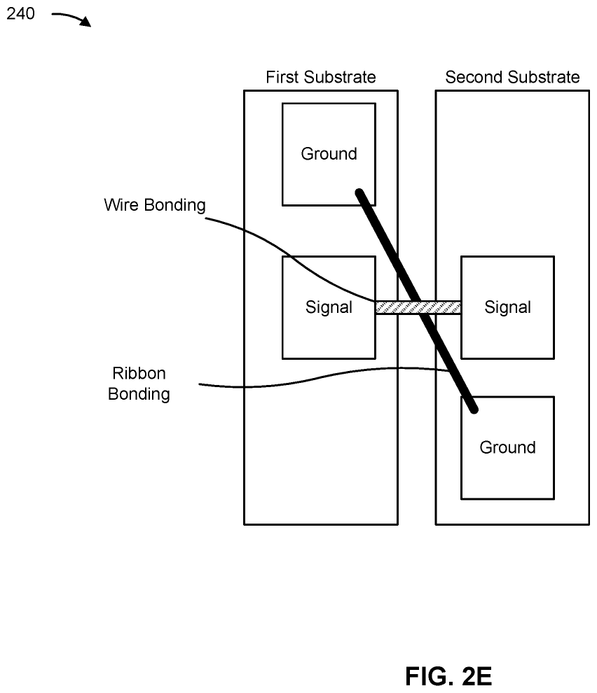

FIGS. 2A-2E are diagrams of an example layouts 200-240 of an electro-optical device associated with a ribbon bonding ground plane. As shown in FIG. 2A, in a first example layout 200, the electro-optical device includes two signal pad pairs (S), rather than the single signal pad pair in FIGS. 1A-1B, and two ground pair pads (G) in a ground-signal-signal-ground (GSSG) coplanar structure arrangement. In this example, a single ribbon bonding extends from a first ground pad on a first side of the two signal pad pairs to a second ground pad on a second side of the two signal pad pairs, such that the single ribbon bonding crosses the two wire bondings for the two signal pad pairs. In this case, the single ribbon bonding serves as a ground plane for the two wire bondings, as shown.

As shown in FIG. 2B, in a second example layout 210, the electro-optical device includes three ground pad pairs and two signal pad pairs arranged in an alternating ground-signal-ground-signal-ground (GSGSG) coplanar structure arrangement. In this case, two ribbon bondings are provided to cross the two wire bondings for the two signal pad pairs. For example, a first ribbon bonding crosses from a first ground pad (on the first substrate) of a first ground pad pair to a second ground pad (on the second substrate) of a second ground pad pair. Similarly, a second ribbon bonding crosses from a third ground pad (on the first substrate) of a third ground pad pair to the second ground pad (on the second substrate) of the second ground pad pair. In other words, the ribbon bondings are bonded to a common ground pad (the second ground pad on the second substrate), in this example.

In contrast, as shown in FIG. 2C, in a third example layout 220, rather than two ribbon bondings sharing a common ground pad, the two ribbon bondings do not share a common ground pad (and extend parallel between the first substrate and the second substrate to cross respective wire bondings of respective signal pad pairs). In other words, the first ribbon bonding extends from a first ground pad on the first substrate to a second ground pad on the second substrate, crossing a first wire bonding for a first signal pad pair. Further, the second ribbon bonding extends from a third ground pad on the first substrate to a fourth ground pad on the second substrate, crossing a second wire bonding for a second signal pad pair.

As shown in FIG. 2D, in a fourth example layout 230, rather than parallel ribbon bondings (as in FIG. 2C) or ribbon bondings meeting at a common ground pad (as in FIG. 2B), ribbon bondings may cross, in some implementations. For example, a first ribbon bonding may extend from a first ground pad on the first substrate to a second ground pad on the second substrate and a second ribbon bonding may extend from a third ground pad on the first substrate to a fourth ground pad on the second substrate. In this case, the first ribbon bonding crosses the second ribbon bonding and both the first ribbon bonding and the second ribbon bonding cross the wire bonding associated with the signal pad pair. In this way, additional ribbon bonding surface area may be present at the crossing with the wire bonding (e.g., present underneath the wire bonding, present above the wire bonding, or one being present underneath and one being present above the wire bonding). For example, as shown, the first ribbon bonding and the second ribbon bonding cross underneath the wire bonding. In another example, both the first ribbon bonding and the second ribbon bonding may cross above the wire bonding. In another example, the first ribbon bonding may pass underneath the wire bonding and the second ribbon bonding may pass above the wire bonding (and cross the first ribbon bonding, thereby sandwiching the wire bonding between the first ribbon bonding and the second ribbon bonding). By having additional ribbon bonding surface area present at the crossing, an amount of parasitic inductance can be further reduced relative to having less ribbon bonding surface area present at the crossing.

As shown in FIG. 2E, in a fifth example layout 240, rather than having ground pad pairs, the electro-optical device may have non-paired ground pads. For example, the first substrate may have a first ground pad on a first side of a first signal pad and the second substrate may not have a ground pad aligned to the first ground pad on the same first side of a second signal pad. Similarly, the second substrate may have a second ground pad on a second side of the second signal pad and the first substrate may not have a ground pad aligned to the second ground pad on the same second side of the first signal pad. In this case, the ribbon bonding extends from the first ground pad to the second ground pad, crossing the wire bonding of the signal pad pair, as shown.

As indicated above, FIGS. 2A-2E are provided as an example. Other examples may differ from what is described with regard to FIGS. 2A-2E. It is contemplated that different quantities of signal pads, ground pads, ribbon connectors, and wire bondings may be possible than what is shown in, for example, FIGS. 2A-2E.

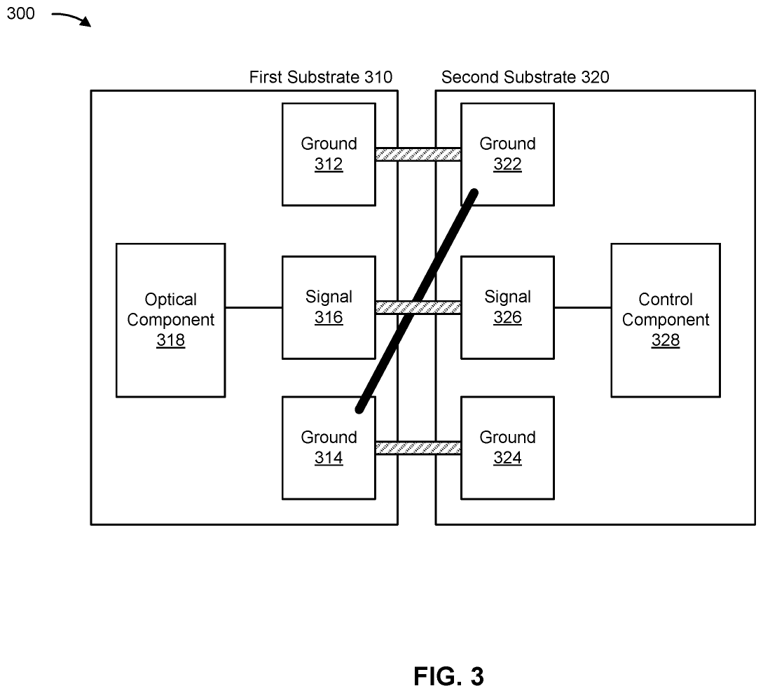

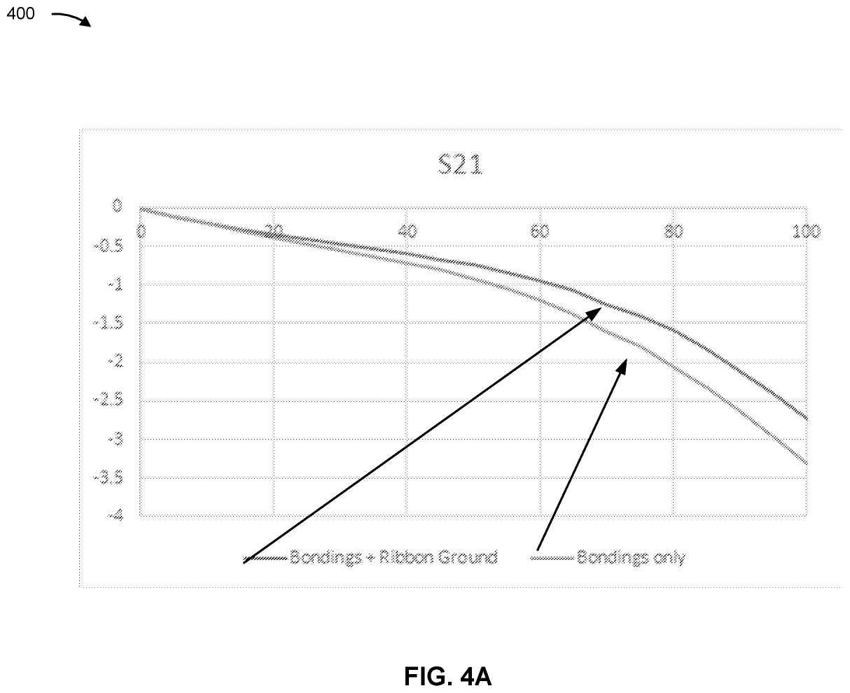

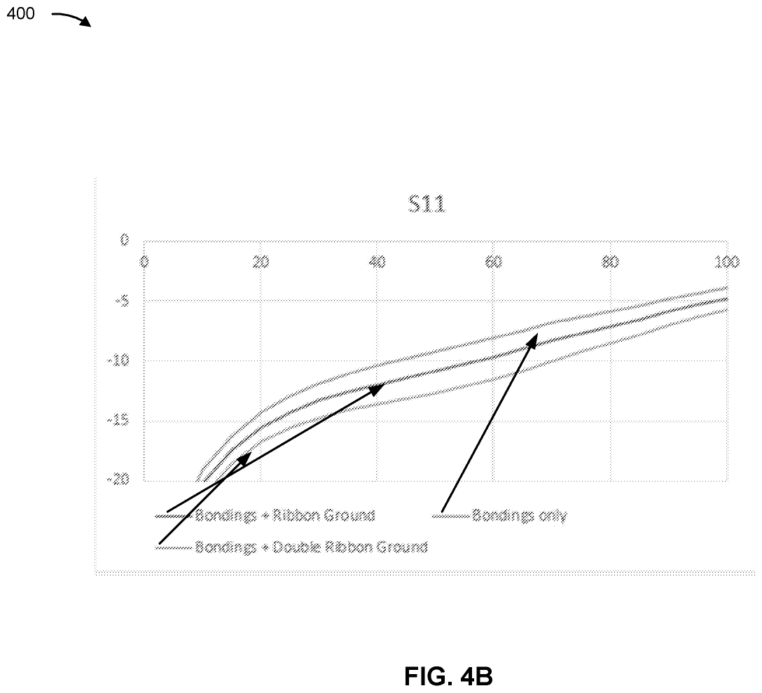

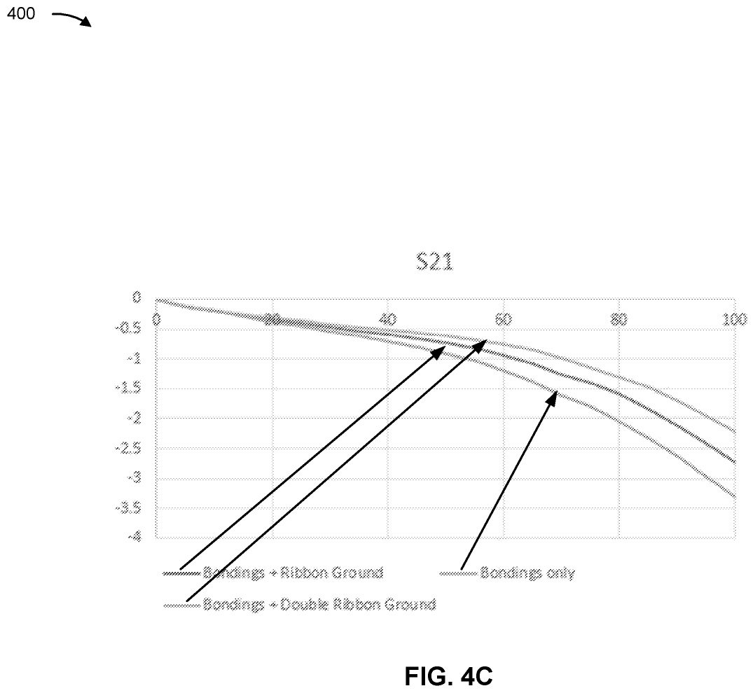

FIG. 3 is a diagram of an example electro-optical device 300 associated with a ribbon bonding ground plane. FIGS. 4A-4C are diagrams of examples 400 of responses of example electro-optical devices with and without a ribbon bonding ground. As shown in FIG. 3, electro-optical device 300 includes a first substrate 310 and a second substrate 320. The first substrate 310 includes a first ground pad 312, a second ground pad 314, and a first signal pad 316. The second substrate 320 includes a third ground pad 322, a fourth ground pad 324, and a second signal pad 326.

As further shown in FIG. 3, the first substrate 310 may connect to the second substrate 320 via a set of wire bondings. Additionally, or alternatively, a ribbon bonding may connect first substrate 310 to second substrate 320 and cross a wire bonding between signal pad 316 and signal pad 326. In some implementations, electro-optical device 300 may include a set of components. For example, first substrate 310 may have an optical component 318 and second substrate 320 may have a control component 328. The optical component 318 may be connected to the control component 328 via signal pads 316 and 326 and a wire bonding. For example, control component 328 may be a signal controller providing high speed radio frequency signals, such as 70 gigahertz (GHz), 100 GHz, 128 GHz, or higher speed RF signals, to optical component 318 via a signal wire connecting signal pads 316 and 326. In some implementations, an inductance associated with the signal wire may be less than a threshold value, such as less than 400 pico-henrys (pH) of inductance.

As shown in FIG. 4A, an S21 response is provided for a first electro-optical device that includes wire bondings and no ribbon bonding ground and for a second electro-optical device that includes wire bondings and a ribbon bonding ground (e.g., the electro-optical device 300). As further shown in FIG. 4A, across a range of frequencies from 0 gigahertz GHz to 100 GHz, including a ribbon bonding ground results in improved S21 performance. For example, at 80 GHz, the first electro-optical device has an S21 response of approximately −2.0 decibels (dB) and the second electro-optical device has an S21 response of approximately −1.5 dB. This shows that including a ribbon grounding improves S21 performance.

As shown in FIGS. 4B and 4C, an S11 and S21 response are provided, respectively, for a first electro-optical device that includes a wire bonding with a ribbon ground, a second electro-optical device that includes a wire bonding with a double ribbon ground (e.g., a first ribbon bonding above and a second ribbon bonding below the wire bonding), and a third electro-optical device that includes a wire bonding without a ribbon ground. As further shown in FIGS. 4A and 4B, across a range of frequencies, S11 and S21 performance is improved by including a ribbon ground and further improved by including a double ribbon ground.

As indicated above, FIGS. 3 and 4A-4C are provided as examples. Other examples may differ from what is described with regard to FIGS. 3 and 4A-4C.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An electro-optical device, comprising:
a first substrate including a first set of ground pads and a first signal pad disposed between a first ground pad and a second ground pad of the first set of ground pads;
a second substrate including a second set of ground pads and a second signal pad disposed between a third ground pad and a fourth ground pad of the second set of ground pads,
wherein the first ground pad is aligned to the third ground pad to form a first ground pad pair, the second ground pad is aligned to the fourth ground pad to form a second ground pad pair, and the first signal pad is aligned to the second signal pad to form a signal pad pair;
a set of wire bondings including a first wire bonding connecting the first ground pad pair, a second wire bonding connecting the second ground pad pair, and a third wire bonding connecting the first signal pad and the second signal pad;
an optical emitter associated with the first substrate and electrically connected to an electrical signal component associated with the second substrate via the third wire bonding; and
a planar ribbon bonding connecting the first ground pad to the fourth ground pad,
wherein the planar ribbon bonding crosses the third wire bonding without contacting the third wire bonding.

2. The electro-optical device of claim 1, wherein the planar ribbon bonding is configured to ground an electrical inductance associated with the third wire bonding.

3. The electro-optical device of claim 1, wherein wire bondings of the set of wire bondings have a circular cross section and the planar ribbon bonding includes rectangular cross section.

4. The electro-optical device of claim 1, wherein the planar ribbon bonding is a flexible connection.

5. The electro-optical device of claim 1, wherein the planar ribbon bonding does not cross the first wire bonding or the second wire bonding.

6. The electro-optical device of claim 1, wherein the planar ribbon bonding is non-insulated.

7. The electro-optical device of claim 1, wherein the planar ribbon bonding includes at least one of:
a metallic material,
a dielectric material, or
or an insulator material.

8. An electro-optical device, comprising:
an optical emitter disposed on a first substrate; and
a signal controller for the optical emitter disposed on a second substrate,
wherein the first substrate and the second substrate include at least one ground pad pair connected by a corresponding at least one ground pad wire bonding,
wherein the first substrate and the second substrate include at least one signal pad pair connected by a corresponding at least one signal pad wire bonding and electrically connecting the optical emitter to the signal controller, and
wherein the first substrate and the second substrate are connected by at least one planar ribbon bonding from at least one first ground of the first substrate to at least one second ground of the second substrate such that the at least one planar ribbon bonding crosses the at least one signal pad wire bonding.

9. The electro-optical device of claim 8, wherein the at least one ground pad pair (G) comprises three ground pad pairs and the at least one signal pad pair (S) comprises two signal pad pairs in a ground-signal-ground-signal-ground (GSGSG) coplanar structure.

10. The electro-optical device of claim 9, wherein the at least one planar ribbon bonding comprises a first planar ribbon bonding crossing a first signal pad pair, of the at least one signal pad pair, and a second planar ribbon bonding crossing a second signal pad pair of the at least one signal pad pair, and
wherein the first planar ribbon bonding and the second planar ribbon bonding are bonded to at least one common ground pad of the at least one ground pad pair.

11. The electro-optical device of claim 9, wherein the at least one planar ribbon bonding comprises a first planar ribbon bonding crossing a first signal pad pair, of the at least one signal pad pair, and a second planar ribbon bonding crossing a second signal pad pair of the at least one signal pad pair, and
wherein the first planar ribbon bonding and the second planar ribbon bonding do not share a common ground pad of the at least one ground pad pair.

12. The electro-optical device of claim 8, wherein the at least one ground pad pair (G) comprises two ground pad pairs and the at least one signal pad pair (S) comprises two signal pad pairs in a ground-signal-signal-ground (GSSG) structure.

13. The electro-optical device of claim 8, wherein a first planar ribbon bonding, of the at least one planar ribbon bonding, crosses, without contacting, a second planar ribbon bonding, of the at least one planar ribbon bonding.

14. The electro-optical device of claim 8, wherein the at least one planar ribbon bonding crosses underneath, over-the-top-of, or a combination thereof the at least one signal pad wire bonding.

15. The electro-optical device of claim 8, wherein the at least one signal pad wire bonding is a high speed radio frequency signal wire with a speed of greater than a first threshold value and an electrical inductance of less than a second threshold value.

16. The electro-optical device of claim 8, wherein a separation between the first substrate and the second substrate is less than a threshold amount.

17. An electro-optical device, comprising:
a first substrate including a first ground pad and a first signal pad;
a second substrate including a second ground pad and a second signal pad,
wherein the first signal pad and the second signal pad form a signal pad pair,
wherein the first substrate is separated from the second substrate by less than a threshold amount,
wherein the first substrate is configured to receive an optical component and the second substrate is configured to receive an electrical component that is couplable to the optical component via a wire bonding between the first signal pad and the second signal pad; and
a planar ribbon bonding connecting the first ground pad to the second ground pad and diagonally crossing the wire bonding.

18. The electro-optical device of claim 17, wherein the planar ribbon bonding has a width to thickness ratio of at least 4:1.

19. The electro-optical device of claim 17, wherein the first ground pad is disposed on a first side of the signal pad pair and the second ground pad is disposed on a second side of the signal pad pair.

20. The electro-optical device of claim 17, wherein a first distance between the first ground pad and the second ground pad is greater than a second distance between the first signal pad and the second signal pad.
